(19) United States
(12) Patent Application Publication
(10) Pub. No.: US 2024/0349490 A1
(43) Pub. Date: Oct. 17, 2024

(54) SEMICONDUCTOR MEMORY DEVICE

(71) Applicant: SAMSUNG ELECTRONICS CO., LTD., SUWON-SI (KR)

(72) Inventors: Huije RYU, SUWON-SI (KR); Hyungki CHO, SUWON-SI (KR)

(21) Appl. No.: 18/501,980

(22) Filed: Nov. 3, 2023

(30) Foreign Application Priority Data
Apr. 12, 2023 (KR) 10-2023-0047951

(51) Int. Cl. H10B 12/00

(52) U.S. Cl. CPC H10B 12/482; H10B 12/315; H10B 12/488

(57) ABSTRACT

A semiconductor memory device includes a bit line that extends in a first direction, semiconductor patterns disposed on the bit line and spaced apart from each other in the first direction and each including a first vertical part, a second vertical part, and a horizontal part, first and second word lines disposed on the horizontal part and respectively adjacent to the first and second vertical parts, and a semiconductor dielectric pattern disposed on the bit line and between the semiconductor patterns. The semiconductor dielectric pattern includes a lower capping pattern, sidewall dielectric patterns spaced apart from each other in the first direction on the lower capping pattern, an air gap between the sidewall dielectric patterns, and an upper capping pattern disposed on the sidewall dielectric patterns. Top surfaces of the sidewall dielectric patterns are at the same height as top surfaces of the first and second vertical parts.

### CROSS-REFERENCE TO RELATED APPLICATION

This U.S. nonprovisional application claims priority under 35 U.S.C § 119 from Korean Patent Application No. 10-2023-0047951, filed on Apr. 12, 2023 in the Korean Intellectual Property Office, the contents of which are herein incorporated by reference in their entirety.

### TECHNICAL FIELD

Embodiments of the present inventive concepts are directed to a semiconductor memory device, and more particularly, to a semiconductor memory device that includes vertical channel transistors and a method of fabricating the same.

### DISCUSSION OF THE RELATED ART

As a design rule of a semiconductor memory device is being reduced, the fabrication technology is being upgraded to increase integration, operating speed, and yield of the semiconductor memory device. Accordingly, transistors with vertical channels are being used to increase their integration, resistance, current driving capability, etc.

### SUMMARY

Some embodiments of the present inventive concepts provide a semiconductor memory device with increased electrical properties and increased reliability.

According to some embodiments of the present inventive concepts, a semiconductor memory device includes: a bit line that extends in a first direction; a plurality of semiconductor patterns disposed on the bit line and that are spaced apart from each other in the first direction, where each of the semiconductor patterns includes a first vertical part, a second vertical part opposite to the first vertical part in the first direction, and a horizontal part that connects the first and second vertical parts to each other; a first word line and a second word line that are disposed on the horizontal part and respectively adjacent to the first vertical part and the second vertical part; and a semiconductor dielectric pattern disposed on the bit line and interposed between the semiconductor patterns. The semiconductor dielectric pattern includes: a lower capping pattern; a plurality of sidewall dielectric patterns disposed on the lower capping pattern and that are spaced apart from each other in the first direction; an air gap interposed between the sidewall dielectric patterns; and an upper capping pattern disposed on the sidewall dielectric patterns. A height of top surfaces of the sidewall dielectric patterns is a same as a height of top surfaces of the first and second vertical parts.

According to some embodiments of the present inventive concepts, a semiconductor memory device includes: a bit line that extends in a first direction; a plurality of semiconductor patterns disposed on the bit line and that are spaced apart from each other in the first direction, wherein each of the semiconductor patterns includes a first vertical part, a second vertical part opposite to the first vertical part in the first direction, and a horizontal part that connects the first and second vertical parts to each other; a first word line and a second word line that are disposed on the horizontal part and respectively adjacent to the first vertical part and the second vertical part; a plurality of landing pads disposed on the first and second vertical parts; and a semiconductor dielectric pattern disposed on the bit line and interposed between the semiconductor patterns. The semiconductor dielectric pattern includes an air gap and a barrier pattern that surrounds the air gap. A sidewall of the barrier pattern includes a metal oxide.

According to some embodiments of the present inventive concepts, a semiconductor memory device includes: a plurality of bit lines that extend in a first direction, where the bit lines are spaced apart from each other in a second direction that is orthogonal to the first direction; a semiconductor patterns disposed on each of the bit lines and that is spaced apart from each other in the first direction, where each of the semiconductor patterns includes a first vertical part, a second vertical part opposite to the first vertical part in the first direction, and a horizontal part that connects the first and second vertical parts to each other; a first word line and a second word line that are disposed on the horizontal part and respectively adjacent to the first vertical part and the second vertical part; a gate dielectric pattern interposed between the first vertical part and the first word line and between the second vertical part and the second word line; a plurality of semiconductor dielectric patterns respectively disposed on each of the bit lines and interposed between the semiconductor patterns, where the semiconductor dielectric patterns are in direct contact with the bit lines; a plurality of landing pads disposed on the first and second vertical parts; and a plurality of data storage patterns respectively disposed on corresponding landing pads. The semiconductor dielectric patterns include: a lower capping pattern disposed on each of the bit lines; a plurality of sidewall dielectric patterns disposed on the lower capping pattern; an air gap formed between the sidewall dielectric patterns; and an upper capping pattern disposed on the sidewall dielectric patterns. Top surfaces of the sidewall dielectric patterns are at a same height as top surfaces of the first and second vertical parts of the semiconductor pattern. The sidewall dielectric patterns include a metal oxide.

### BRIEF DESCRIPTION OF DRAWINGS

FIG. 1 is a block diagram of a semiconductor memory device according to some embodiments of the present inventive concepts.

FIG. 2 is a simplified perspective view of a semiconductor memory device according to some embodiments of the present inventive concepts.

FIG. 3 is a plan view of a semiconductor memory device according to some embodiments of the present inventive concepts.

FIGS. 4, 5, and 6 are cross-sectional views respectively taken along lines A-A′, B-B′, and C-C′ of FIG. 3.

FIG. 7A is a cross-sectional view taken along line D-D′ of FIG. 3.

FIG. 7B is an enlarged view of section P depicted in FIG. 7A that partially shows a semiconductor memory device according to some embodiments of the present inventive concepts.

FIGS. 8A to 8H are cross-sectional views that illustrate a method of fabricating a semiconductor memory device according to some embodiments of the present inventive concepts.

### DETAILED DESCRIPTION

It will be hereinafter described a semiconductor memory device and a method of fabricating the same according to some embodiments of the present inventive concepts in conjunction with the accompanying drawings.

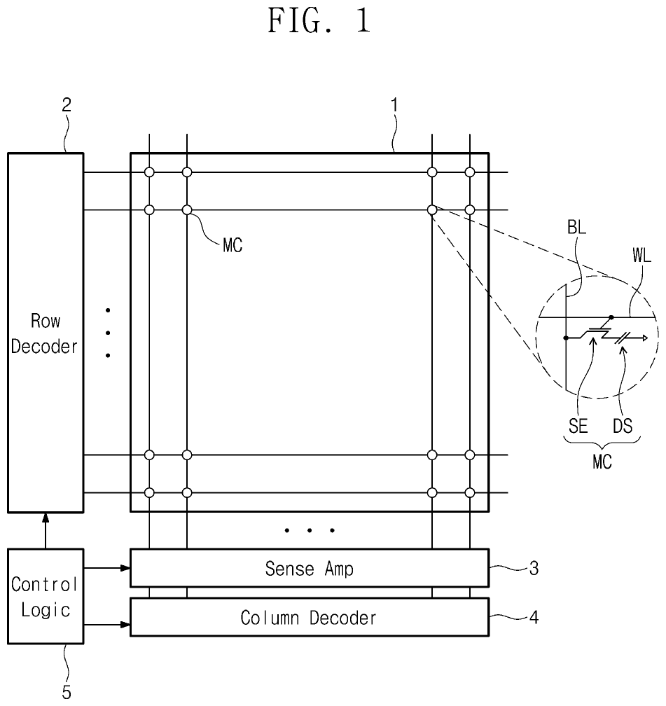

FIG. 1 is a block diagram of a semiconductor memory device according to some embodiments of the present inventive concepts.

Referring to FIG. 1, in an embodiment, a semiconductor memory device includes a memory cell array 1, a row decoder 2, a sense amplifier 3, a column decoder 4, and a control logic 5.

The memory cell array 1 includes a plurality of memory cells MC that are two-dimensionally or three-dimensionally arranged. Each of the memory cells MC is connected between a word line WL and a bit line BL that cross each other.

Each of the memory cells MC includes a selection element SE and a data storage element DS, and the selection element SE and the data storage element DS are electrically connected in series. The selection element SE is connected between the data storage element DS and the word line WL, and the data storage element DS is connected through the selection element SE to the bit line BL. The selection element SE may be a field effect transistor (FET), and the data storage element DS is one of a capacitor, a magnetic tunnel junction pattern, or a variable resistor. For example, the selection element SE includes a transistor whose gate electrode is connected to the word line WL and whose source/drain terminals are connected to the bit line BL and the data storage element DS.

The row decoder 2 decodes an address received from an external source and selects one of the word lines WL of the memory cell array 1. The address that is decoded by the row decoder 2 is provided to a row driver, and in response to a control operation of the control circuits, the row driver transmits a voltage to a selected word line WL and each of non-selected word lines WL.

In response to an address that is decoded by the column decoder 4, the sense amplifier 3 detects and amplifies a voltage difference between a selected bit line BL and a reference bit line, and then outputs the amplified voltage difference.

The column decoder 4 provides a data delivery pathway between the sense amplifier 3 and an external device, such as a memory controller. The column decoder 4 decodes an address received from an external source and selects one of the bit lines.

The control logic 5 generates control signals that control operations that write data to the memory cell array 1 and/or read data from the memory cell array 1.

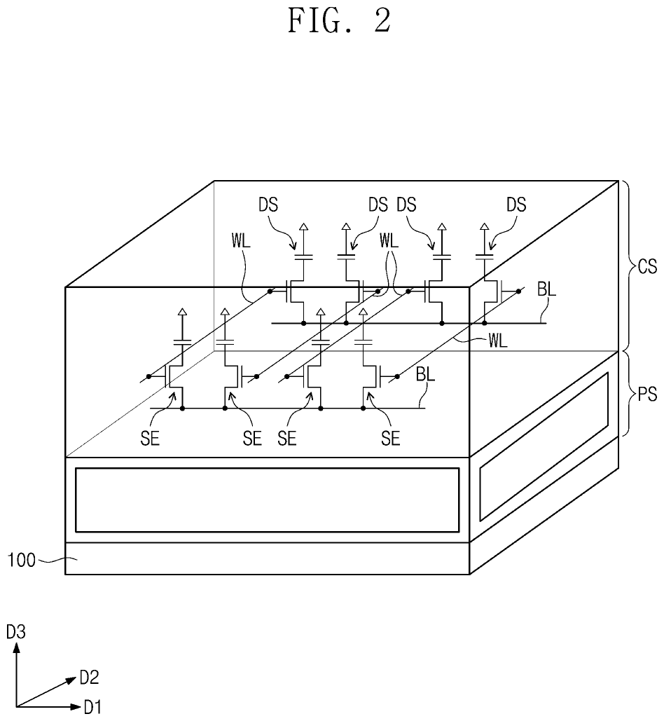

FIG. 2 is a simplified perspective view of a semiconductor memory device according to some embodiments of the present inventive concepts.

Referring to FIG. 2, a semiconductor memory device according to some embodiments of the present inventive concepts includes a peripheral circuit structure PS disposed on a substrate 100 and a cell array structure CS disposed on the peripheral circuit structure PS.

The peripheral circuit structure PS includes core/peripheral circuits formed on the substrate 100. The core/peripheral circuits include the row and column decoders (see 2 and 4 of FIG. 1), the sense amplifier (see 3 of FIG. 1), and the control logics (see 5 of FIG. 1). The peripheral circuit structure PS are provided in a third direction D3 between the substrate 100 and the cell array structure CS, where the third direction D3 is perpendicular to a top surface of the substrate 100.

The cell array structure CS includes bit lines BL, word lines WL, and memory cells (see MC of FIG. 1) formed between the bit lines BL and the word lines WL. The memory cells (see MC of FIG. 1) are two-dimensionally or three-dimensionally arranged on a plane that extends in first and second directions D1 and D2 that are parallel to the top surface of the substrate 100 and intersect each other. Each of the memory cells (see MC of FIG. 1) includes, as described above, a selection element SE and a data storage element DS.

According to some embodiments, a vertical channel transistor (VCT) is included as the selection element SE of each memory cell (see MC of FIG. 1). The vertical channel transistor has a structure whose channel length extends in a direction, such as the third direction D3, perpendicular to the top surface of the substrate 100. In addition, each memory cell (see MC of FIG. 1) includes a capacitor as the data storage element DS.

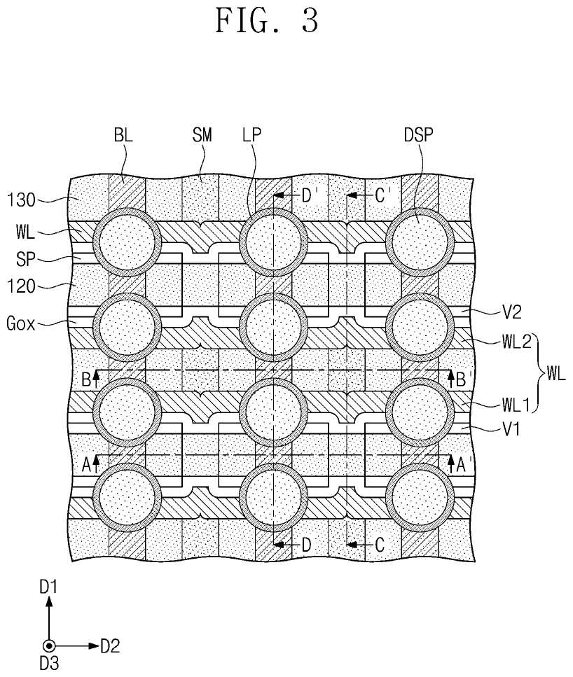

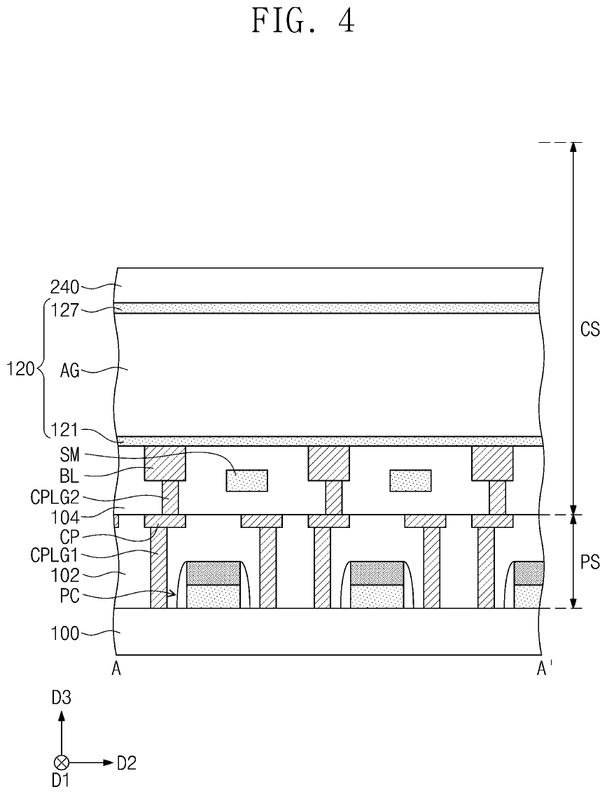

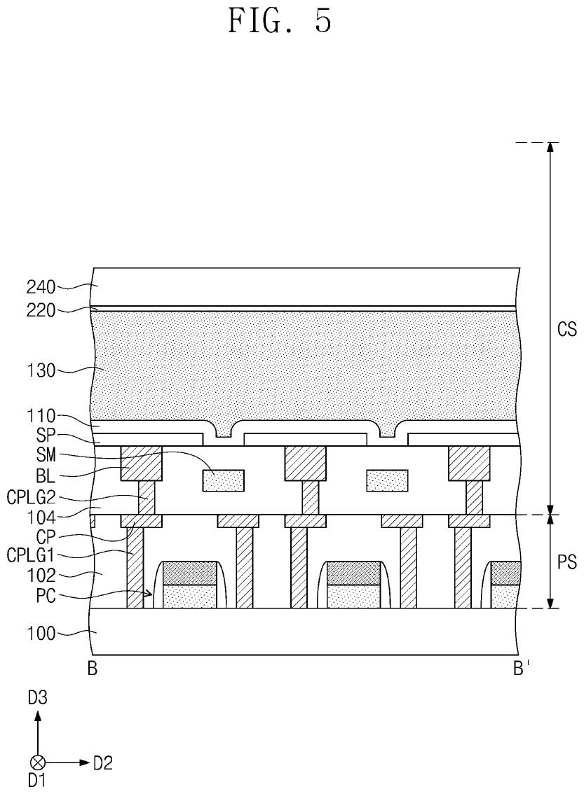

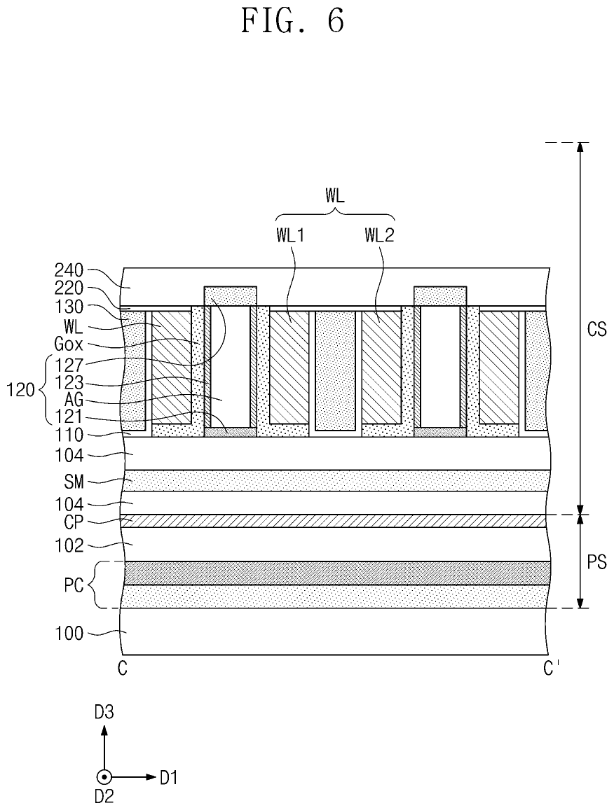

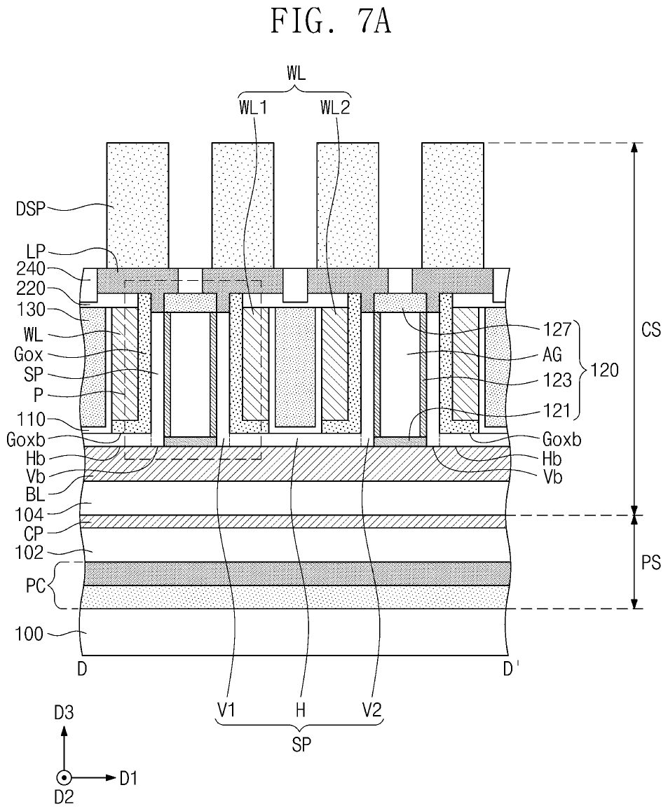

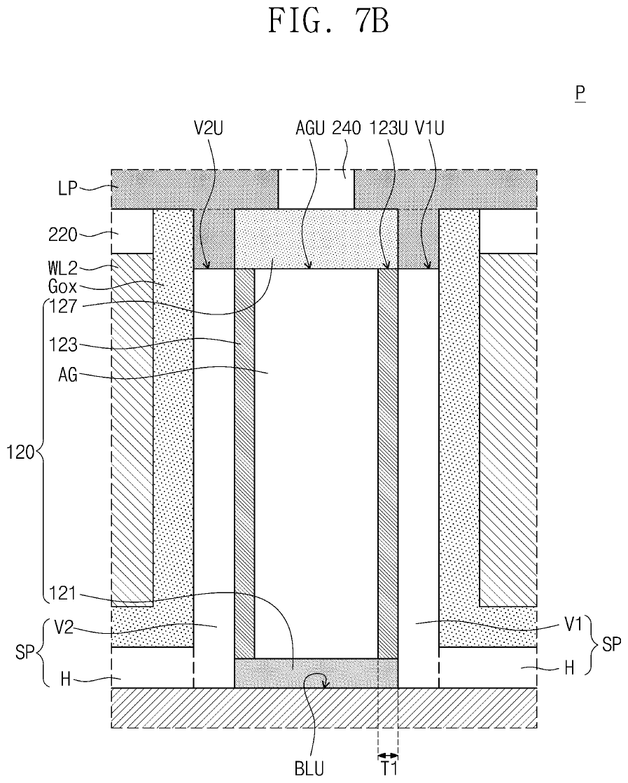

FIG. 3 is a plan view of a semiconductor memory device according to some embodiments of the present inventive concepts. FIGS. 4, 5, and 6 are cross-sectional views respectively taken along lines A-A′, B-B′, and C-C′ of FIG. 3. FIG. 7A is a cross-sectional view taken along line D-D′ of FIG. 3. FIG. 7B is an enlarged view of section P of FIG. 7A.

Referring to FIGS. 3 to 6 and 7A, a semiconductor memory device according to some embodiments of the present inventive concepts includes a peripheral circuit structure PS disposed on a substrate 100 and a cell array structure CS disposed on the peripheral circuit structure PS.

The substrate 100 is a semiconductor substrate. The substrate 100 is, for example, one of a silicon substrate, a germanium substrate, or a silicon-germanium substrate.

The peripheral circuit structure PS includes a peripheral gate structure PC, peripheral contact pads CP, and peripheral contact plugs CPLG1 that are integrated and formed on the substrate 100, and also includes a first interlayer dielectric layer 102 that covers the peripheral gate structure PC, the peripheral contact pads CP, and the peripheral contact plugs CPLG1. The peripheral gate structure PC includes a sense amplifier 3 of FIG. 1.

The cell array structure CS includes memory cells that include a vertical channel transistor. The cell array structure CS includes a plurality of cell contact plugs CPLG2, a plurality of bit lines BL, a plurality of shield structures SM, a second interlayer dielectric layer 104, a plurality of semiconductor patterns SP, a plurality of word lines WL, a plurality of gate dielectric patterns Gox, and a plurality of data storage patterns DSP. The second interlayer dielectric layer 104 covers the cell contact plugs CPLG2 and the shield structures SM.

The peripheral gate structures PC of the peripheral circuit structure PS are electrically connected to the bit lines BL through the peripheral contact plugs CPLG1, the peripheral contact pads CP, and the cell contact plugs CPLG2. Each of the first and second interlayer dielectric layers 102 and 104 include multi-stacked dielectric layers, and include at least one of silicon oxide, silicon nitride, silicon oxynitride, or low-k dielectrics.

The bit line BL on the substrate 100 extends along the first direction D1. The bit line BL is provided in plural, and the plurality of bit lines BL are spaced apart from each other in the second direction D2. Each bit line BL is electrically connected through the cell contact plug CPLG2 to the peripheral contact pad CP.

The bit line BL includes, for example, at least one of doped polysilicon, a metal, such as Al, Cu, Ti, Ta, Ru, W, Mo, Pt, Ni, or Co, a conductive metal nitride, such as TiN, TaN, WN, NbN, TiAIN, TiSiN, TaSiN, or RuTiN, a conductive metal silicide, or a conductive metal oxide, such as PtO, RuO₂, IrO₂, SRO(SrRuO₃), BSRO((Ba,Sr) RuO₃), CRO(CaRuO₃), or LSCo, but embodiments of the present inventive concepts are not necessarily limited thereto. The bit line BL may include a single layer or multiple layers of one or more materials disclosed above. In some embodiments, the bit line BL includes a two-dimensional semiconductor material, such as graphene, a carbon nano-tube, or any combination thereof.

The shield structures SM are correspondingly provided between the bit lines BL, and extend along the first direction D1. The shield structures SM include a conductive material, such as a metal. The shield structures SM are disposed in the second interlayer dielectric layer 104, and their top surfaces are located lower than those of the bit lines BL.

The shield structures SM are formed of a conductive material, and may include an air gap or a void therein. Alternatively, air gaps are provided in the second interlayer dielectric layer 104 instead of the shield structures SM.

The semiconductor pattern SP is disposed on the bit line BL. The semiconductor pattern SP is provided in plural. The plurality of semiconductor patterns SP are spaced apart from each other in the first and second directions D1 and D2.

The semiconductor pattern SP includes a first vertical part V1, a second vertical part V2 opposite to the first vertical part V1 in the first direction D1, and a horizontal part H that connects the first and second vertical parts V1 and V2 to each other. The horizontal part H is adjacent to lower portions of the first and second vertical parts V1 and V2 and connects the first and second vertical parts V1 and V2 to each other. A bottom surface Hb of the horizontal part H and bottom surfaces Vb of the first and second vertical parts V1 and V2 are in direct contact with a top surface of the bit line BL.

The horizontal part H of the semiconductor pattern SP includes a common source/drain region, and upper portions of the first and second vertical parts V1 and V2 include first and second source/drain regions, respectively. The first vertical part V1 includes a first channel region located between the common source/drain region and the first source/drain region, and the second vertical part V2 includes a second channel region located between the common source/drain region and the second source/drain region. Each of the first and second vertical parts V1 and V2 is electrically connected to the bit line BL. For example, a semiconductor memory device according to the present inventive concepts has a structure in which a pair of vertical channel transistors share one bit line BL.

The semiconductor pattern SP includes an oxide semiconductor, such as at least one of InₓGa_{y}Zn₂O, InₓGa_{y}Si_{z}O, InₓSn_{y}Zn₂O, InₓZn_{y}O, ZnₓO, ZnₓSn_{y}O, ZnₓO_{y}N, ZrₓZn_{y}Sn₂O, SnₓO, HfₓIn_{y}Zn₂O, GaₓZn_{y}Sn₂O, AlₓZn_{y}Sn₂O, YbₓGa_{y}Zn₂O, or InₓGa_{y}O, but embodiments of the present inventive concepts are not necessarily limited thereto. For example, the semiconductor pattern SP includes indium-gallium-zinc oxide (IGZO). The semiconductor pattern SP may have a single layer or multiple layers of the oxide semiconductors. The semiconductor pattern SP may include an amorphous, a crystalline, or a polycrystalline oxide semiconductor.

In some embodiments, the semiconductor pattern SP has a bandgap energy greater than that of silicon. For example, the semiconductor pattern SP has a bandgap energy of about 1.5 eV to about 5.6 eV. The semiconductor pattern SP has an optimum channel performance when its bandgap energy ranges from about 2.0 eV to about 4.0 eV. The semiconductor pattern SP may be polycrystalline or amorphous, but embodiments of the present inventive concepts are not necessarily limited thereto. In some embodiments, the semiconductor pattern SP includes a two-dimensional semiconductor material, such as graphene, a carbon nano-tube, or any combination thereof.

The word line WL is disposed between the first vertical part V1 and the second vertical part V2. The word line WL is provided in plural. The word lines WL extend in the second direction D2 and are spaced apart from each other in the first direction D1.

Each of the word lines WL includes a first word line WL1 and a second word line WL2, and the first word line WL1 and the second word line WL2 are opposite to each other in the first direction D1. The first word line WL1 covers an inner surface of the first vertical part V1, and the inner surface of the first vertical part V1 is a lateral surface that faces the second vertical part V2.

The first word line WL1 is adjacent to and controls the first channel region of the first vertical part V1. The second word line WL2 covers an inner surface of the second vertical part V2, and the inner surface of the second vertical part V2 is a lateral surface that faces the first vertical part V1. The second word line WL2 is adjacent to and controls the second channel region of the second vertical part V2.

The word line WL includes, for example, at least one of doped polysilicon, a metal, such as Al, Cu, Ti, Ta, Ru, W, Mo, Pt, Ni, or Co, a conductive metal nitride, such as TiN, TaN, WN, NbN, TiAIN, TiSiN, TaSiN, or RuTiN, a conductive metal silicide, or a conductive metal oxide, such as PtO, RuO₂, IrO₂, SRO(SrRuO₃), BSRO((Ba,Sr)RuO₃), CRO(CaRuO₃), or LSCo, but embodiments of the present inventive concepts are not necessarily limited thereto. The word line WL may have a single layer or multiple layers of one or more materials described above. In some embodiments, the word line WL includes a two-dimensional semiconductor material, such as graphene, a carbon nano-tube, or any combination thereof.

The gate dielectric pattern Gox is interposed between the semiconductor pattern SP and the word line WL. For example, the gate dielectric pattern Gox is interposed between the first word line WL1 and the inner surface of the first vertical part V1 and between the second word line WL2 and the inner surface of the second vertical part V2. The gate dielectric pattern Gox further extends between the horizontal part H and the word line WL. The gate dielectric pattern Gox separates the word line WL from the semiconductor pattern SP. The gate dielectric pattern Gox has a uniform thickness and covers the semiconductor pattern SP.

As shown in FIG. 7A, in an embodiment, a plurality of gate dielectric patterns Gox are correspondingly interposed between the first vertical part V1 and the first word line WL1 and between the second vertical part V2 and the second word line WL2, are disposed on the horizontal part H, and are separated from each other without being connected to each other. For example, the gate dielectric patterns Gox are spaced apart from each other on the horizontal part H.

Alternatively, in some embodiments, the gate dielectric pattern Gox are interposed between the first vertical part V1 and the first word line WL1 and between the second vertical part V2 and the second word line WL2, and are connected with each other on the horizontal part H.

The gate dielectric pattern Gox includes at least one of silicon oxide, silicon oxynitride, or a high-k dielectric whose dielectric constant is greater than that of silicon oxide. The high-k dielectric is one of a metal oxide or a metal oxynitride. For example, the high-k dielectric includes at least one of HfO₂, HfSiO, HfSiON, HfTaO, HfTiO, HfZrO, ZrO₂, Al₂O₃, or any combination thereof, but embodiments of the present inventive concepts are not necessarily limited thereto.

A semiconductor dielectric pattern 120 is disposed on the bit line BL. The semiconductor dielectric pattern 120 is interposed between adjacent semiconductor patterns SP in the first direction D1. The semiconductor dielectric pattern 120 is provided in plural. The plurality of semiconductor dielectric patterns 120 extend in the second direction D2 while crossing the bit lines BL, and are spaced apart from each other in the first direction D1. The semiconductor dielectric pattern 120 are spaced apart from the gate dielectric pattern Gox.

The semiconductor dielectric pattern 120 may include an air gap AG and a barrier pattern. The barrier pattern is in direct contact with the semiconductor patterns SP. The barrier pattern surrounds the air gap AG. A sidewall of the barrier pattern includes a metal oxide. For example, the barrier pattern includes at least one of hafnium (Hf) oxide, silicon (Si) oxide, aluminum (Al) oxide, zirconium (Zr) oxide, titanium (Ti) oxide, tantalum (Ta) oxide, niobium (Nb) oxide, lanthanum (La) oxide, barium (Ba) oxide, strontium (Sr) oxide, yttrium (Y) oxide, or ruthenium (Lu) oxide.

Referring to FIGS. 7A and 7B, in an embodiment, the barrier pattern includes a lower capping pattern 121, sidewall dielectric patterns 123, and an upper capping pattern 127. The lower capping pattern 121 is disposed on a top surface BLU of the bit line BL. The lower capping pattern 121 is adjacent to the bit line BL. The lower capping pattern 121 is in direct contact with the top surface BLU of the bit line BL. The lower capping pattern 121 includes a capping material. For example, the lower capping pattern 121 includes one or more of silicon nitride or silicon oxynitride.

The sidewall dielectric patterns 123 are disposed on the lower capping pattern 121. The sidewall dielectric patterns 123 are spaced apart from each other in the first direction D1. The sidewall dielectric patterns 123 each have a lateral surface aligned with one of lateral surfaces of the lower capping pattern 121. The sidewall dielectric patterns 123 have top surfaces 123U that are located at the same height (level) as a top surface VIU of the first vertical part V1 of the semiconductor pattern SP and a top surface V2U of the second vertical part V2 of the semiconductor pattern SP. The sidewall dielectric patterns 123 is in direct contact with the semiconductor patterns SP.

Each of the sidewall dielectric patterns 123 has a thickness T1 in the first direction D1. The thickness T1 of each of the sidewall dielectric patterns 123 ranges from about 0.1 nm to about 5 nm. The sidewall dielectric patterns 123 includes a metal oxide. For example, the sidewall dielectric patterns 123 include at least one of hafnium (Hf) oxide, silicon (Si) oxide, aluminum (Al) oxide, zirconium (Zr) oxide, titanium (Ti) oxide, tantalum (Ta) oxide, niobium (Nb) oxide, lanthanum (La) oxide, barium (Ba) oxide, strontium (Sr) oxide, yttrium (Y) oxide, or ruthenium (Lu) oxide.

The air gap AG is disposed on the lower capping pattern 121. The air gap AG is disposed between the sidewall dielectric patterns 123. The sidewall dielectric patterns 123 are spaced apart from each other by the air gap AG. The air gap AG has a top surface AGU located at the same height (level) as the top surface VIU of the first vertical part V1 of the semiconductor pattern SP and the top surface V2U of the second vertical part V2 of the semiconductor pattern SP. The top surface AGU of the air gap AG is coplanar with the top surfaces 123U of the sidewall dielectric patterns 123, the top surface VIU of the first vertical part V1 of the semiconductor pattern SP, and the top surface V2U of the second vertical part V2 of the semiconductor pattern SP. The air gap AG is in direct contact with the lower capping pattern 121 and the sidewall dielectric patterns 123. The air gap AG includes air.

The upper capping pattern 127 is disposed on the air gap AG and the sidewall dielectric patterns 123. The upper capping pattern 127 is spaced apart from the lower capping pattern 121 by the air gap AG. The upper capping pattern 127 is in direct contact with the top surfaces 123U of the sidewall dielectric patterns 123 and the top surface AGU of the air gap AG. A lateral surface of the upper capping pattern 127 is aligned with those of the sidewall dielectric patterns 123. The upper capping pattern 127 includes a capping material. For example, the upper capping pattern 127 includes one or more of silicon nitride or silicon oxynitride.

The air gap AG is surrounded by the lower capping pattern 121, the upper capping pattern 127, and the sidewall dielectric patterns 123. The sidewall dielectric patterns 123 connect the upper capping pattern 127 to the lower capping pattern 121.

Referring back to FIGS. 3 to 6 and 7A, in an embodiment, a first dielectric pattern 130 is disposed on and between the first word line WL1 and the second word line WL2 of the word line WL. The first dielectric pattern 130 is provided in plural. The plurality of first dielectric patterns 130 extend in the second direction D2 while crossing the bit line BL, and are spaced apart from each other in the first direction D1. The first dielectric patterns 130 and the semiconductor dielectric patterns 120 are alternately arranged in the first direction D1. The first dielectric pattern 130 includes, for example, at least one of silicon oxide, silicon nitride, silicon oxynitride, or a low-k dielectric.

A protection pattern 110 is interposed between the word line WL and the first dielectric pattern 130. The protection pattern 110 covers an inner surface of the word line WL. The protection pattern 110 includes at least one of silicon oxide, silicon nitride, or silicon oxynitride.

A capping pattern 220 is disposed on a top surface of the word line WL. The capping pattern 220 covers a top surface of the protection pattern 110 and a top surface of the first dielectric pattern 130. The capping pattern 220 extends along the second direction D2. The capping pattern 220 includes, for example, at least one of silicon oxide, silicon nitride, or silicon oxynitride.

Landing pads LP are disposed on the first and second vertical parts V1 and V2 of the semiconductor pattern SP. The landing pads LP are in direct contact with and electrically connected to the first and second vertical parts V1 and V2. The upper capping pattern 127 is adjacent to the landing pads LP. The landing pad LP is in direct contact with the upper capping pattern 127. When viewed in a plan view, the landing pads LP are spaced apart from each other in the first and second directions D1 and D2, and are arranged in one of a matrix pattern, a zigzag pattern, a honeycomb pattern, or any other suitable pattern. When viewed in a plan view, the landing pads LP each have one of a circular shape, an oval shape, a rectangular shape, a square shape, a rhombic shape, a hexagonal shape, or any other suitable shape.

The landing pads LP are formed of one or more of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but embodiments of the present inventive concepts are not necessarily limited thereto.

A third interlayer dielectric layer 240 fills a space between the landing pads LP on the first dielectric pattern 130 and the semiconductor dielectric patterns 120. The third interlayer dielectric layer 240 includes, for example, at least one of silicon oxide, silicon nitride, or silicon oxynitride, and may include a single layer or multiple layers.

Data storage patterns DSP are correspondingly disposed on the landing pads LP. The data storage patterns DSP are electrically connected through the landing pads LP to the first and second vertical parts V1 and V2 of the semiconductor pattern SP.

According to an embodiment, the data storage patterns DSP are capacitors, and include bottom and top electrodes and a capacitor dielectric layer interposed between the bottom and top electrodes. For example, the bottom electrode is in contact with the landing pad LP, and when viewed in a plan view, have one of a circular shape, an oval shape, a rectangular shape, a square shape, a rhombic shape, a hexagonal shape, or any other suitable shape.

Alternatively, the data storage patterns DSP are each a variable resistance pattern that is switched between two resistance states by an applied electrical pulse. For example, the data storage patterns DSP include at least one of a phase-change material whose crystalline state changes based on an amount of current, a perovskite compound, a transition metal oxide, a magnetic material, a ferromagnetic material, or an antiferromagnetic material.

In a semiconductor memory device according to some embodiments of the present inventive concepts, the semiconductor dielectric pattern 120 disposed between the semiconductor patterns SP includes the air gap AG and the sidewall dielectric patterns 123 that include a metal oxide. Therefore, the semiconductor patterns SP have increased mobility, and a parasitic capacitance can be prevented. In addition, as the semiconductor dielectric pattern 120 includes the upper capping pattern 127, the landing pads LP have increased resistance, and the introduction of hydrogen can be blocked. In conclusion, a semiconductor memory device has increased reliability and electrical properties.

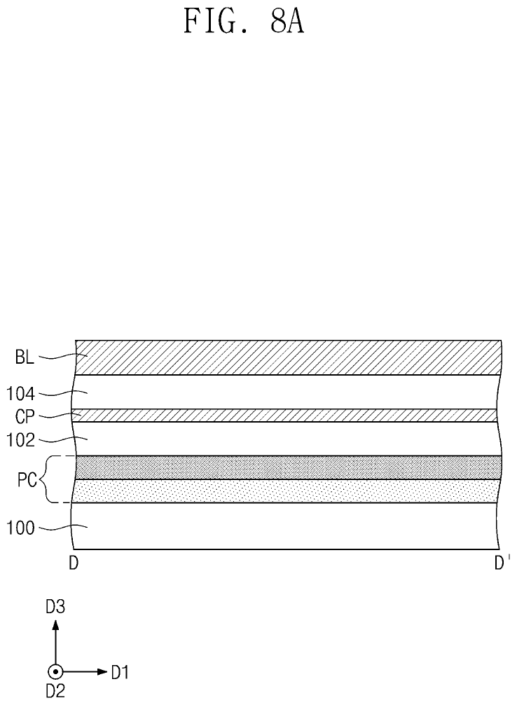

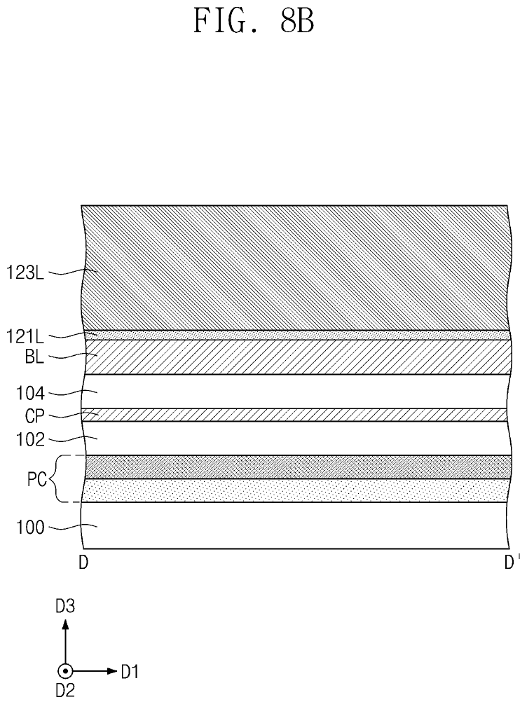

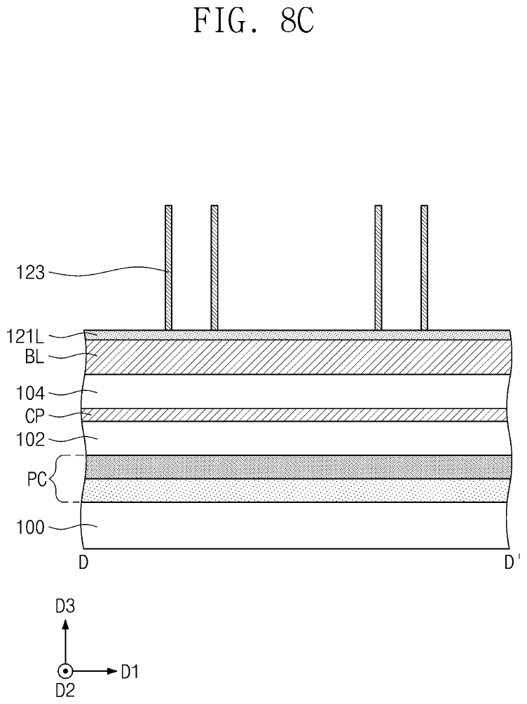

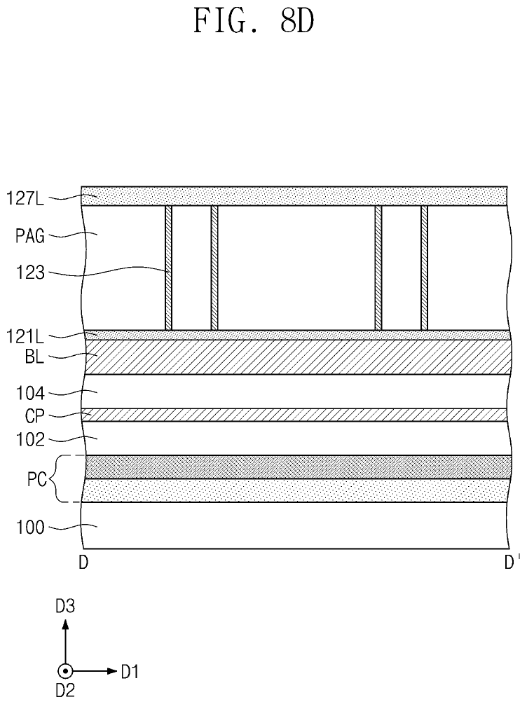

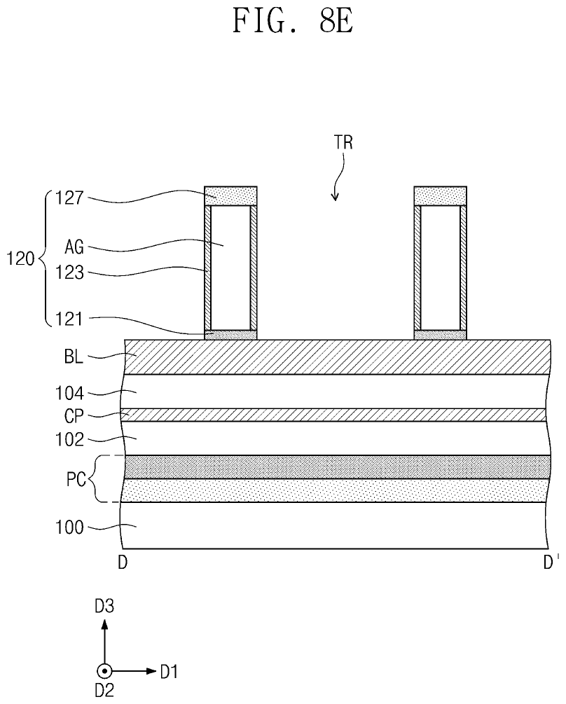

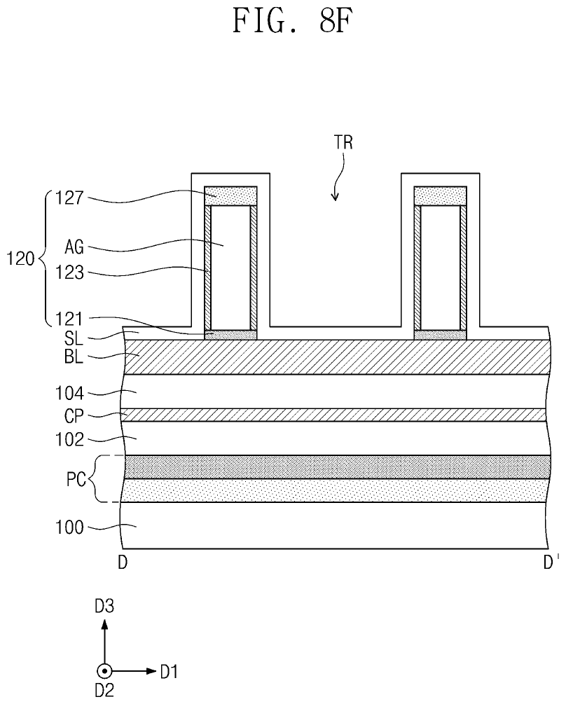

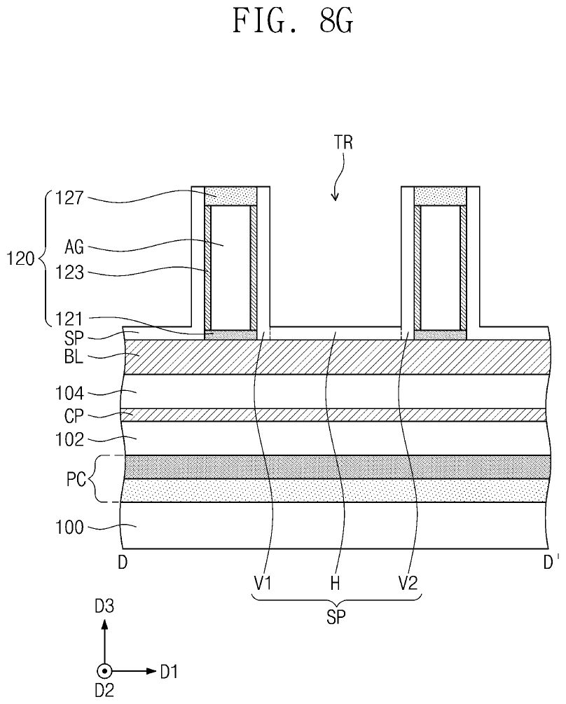

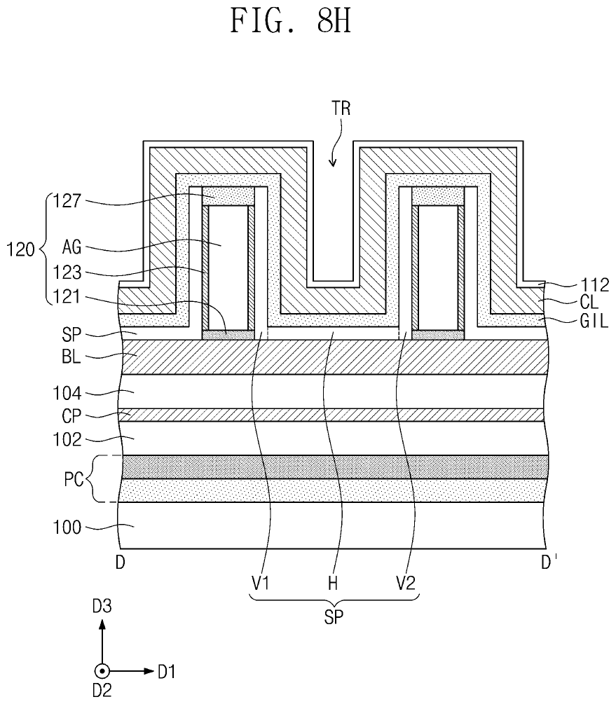

FIGS. 8A to 8H are cross-sectional views that illustrate a method of fabricating a semiconductor memory device according to some embodiments of the present inventive concepts. A repeated description of components described above may be omitted or summarized in the interest of brevity of explanation.

Referring to FIGS. 3 and 8A, in an embodiment, a bit line BL is formed on a substrate 100. A plurality of bit lines BL are formed. The bit lines BL are formed to extend in a first direction D1 and to be spaced apart from each other in a second direction D2. The bit lines BL are electrically connected with underlying wiring lines. The formation of the bit lines BL includes depositing a bit line layer on the substrate 100 and patterning the bit line layer to form the bit lines BL.

Referring to FIG. 8B, in an embodiment, a lower capping layer 121L and a sidewall dielectric layer 123L are sequentially formed on the bit line BL. The lower capping layer 121L and the sidewall dielectric layer 123L are formed to extend in the first direction D1 and to be spaced apart from each other in the second direction D2. The formation of the lower capping layer 121L and the sidewall dielectric layer 123L includes depositing the lower capping layer 121L and the sidewall dielectric layer 123L by using at least one of a physical vapor deposition (PVD), a thermal chemical vapor deposition (thermal CVD), a low-pressure chemical vapor deposition (LPCVD), a plasma enhanced chemical vapor deposition (PECVD), or an atomic layer deposition (ALD).

Referring to FIG. 8C, in an embodiment, sidewall dielectric patterns 123 are formed on the lower capping layer 121L. The formation of the sidewall dielectric patterns 123 includes forming first mask patterns on the sidewall dielectric layer 123L, and using the first mask patterns as an etching mask to etch the sidewall dielectric layer 123L. The etching process partially exposes a top surface of the lower capping layer 121L.

Referring to FIG. 8D, in an embodiment, a first sacrificial pattern PAG is formed on the lower capping layer 121L. The first sacrificial pattern PAG fills a space between the sidewall dielectric patterns 123 on the lower capping layer 121L. The formation of the first sacrificial pattern PAG includes forming a first sacrificial pattern layer on the lower capping layer 121L, and then performing a planarization process that exposes top surfaces of the sidewall dielectric patterns 123. The formation of the first sacrificial pattern layer includes, for example, a spin coating process.

An upper capping layer 127L is formed on the first sacrificial pattern PAG. The upper capping layer 127L covers a top surface of the first sacrificial pattern PAG and top surfaces of the sidewall dielectric patterns 123. The formation of the upper capping layer 127L includes depositing the upper capping layer 127L on the first sacrificial pattern PAG and the sidewall dielectric patterns 123.

The first sacrificial pattern PAG includes a material that differs from that of the lower capping layer 121L and that of the upper capping layer 127L. The first sacrificial pattern PAG includes a material that has an etch selectivity with respect to the lower capping layer 121L and the upper capping layer 127L. For example, the first sacrificial pattern PAG includes a photoresist material.

Referring to FIG. 8E, in an embodiment, semiconductor dielectric patterns 120 are formed on the bit line BL. The formation of the semiconductor dielectric patterns 120 includes etching the upper capping layer 127L, the first sacrificial pattern PAG, and the lower capping layer 121L, and then forming an air gap AG. The etching process includes forming second mask patterns on the upper capping layer 127L, and then using the second mask patterns as an etching mask to sequentially etch the upper capping layer 127L, the first sacrificial pattern PAG, and the lower capping layer 121L to form an upper capping pattern 127 and a lower capping pattern 121. The formation of the air gap AG includes removing a residue of the first sacrificial pattern PAG. The residue of the first sacrificial pattern PAG can be removed by an ashing process and/or a strip process. A trench region TR is formed between the semiconductor dielectric patterns 120, thereby exposing a portion of the bit line BL.

Referring to FIG. 8F, in an embodiment, a semiconductor layer SL is formed that covers an entire top surface of the substrate 100. The formation of the semiconductor layer SL includes depositing the semiconductor layer SL by using at least one of a physical vapor deposition (PVD), a thermal chemical deposition process (thermal CVD), a low pressure chemical vapor deposition (LPCVD), a plasma enhanced chemical vapor deposition (PECVD), or an atomic layer deposition (ALD). The semiconductor layer SL conformally covers exposed lateral surfaces of the semiconductor dielectric patterns 120 and the portion of the bit line BL exposed by the trench region TR. The semiconductor layer SL fills a portion of the trench region TR.

Referring to FIG. 8G, in an embodiment, a portion of the semiconductor layer SL is removed. The partial removal of the semiconductor layer SL includes removing the semiconductor layer SL from regions between adjacent bit lines BL in the second direction D2 and from regions that extend in the first direction D1, and removing the semiconductor layer SL from top surfaces of the semiconductor dielectric patterns 120. The partial removal separates the semiconductor layer SL into a plurality of semiconductor patterns SP. Each of the semiconductor patterns SP includes a first vertical part V1, a second vertical part V2, and a horizontal part H that connects the first and second vertical parts V1 and V2 to each other.

Referring to FIG. 8H, in an embodiment, a gate dielectric layer GIL, a conductive layer CL, and a protection layer 112 are sequentially formed that cover the entire top surface of the substrate 100. The gate dielectric layer GIL, the conductive layer CL, and the protection layer 112 fill a portion of the trench region TR and conformally cover inner surfaces of the first and second vertical parts V1 and V2, a top surface of the horizontal part H, and the top surfaces of the semiconductor dielectric patterns 120. The formation of the gate dielectric layer GIL, the conductive layer CL, and the protection layer 112 includes sequentially depositing the gate dielectric layer GIL, the conductive layer CL, and the protection layer 112 by using at least one of a physical vapor deposition (PVD), a thermal chemical deposition process (thermal CVD), a low pressure chemical vapor deposition (LPCVD), a plasma enhanced chemical vapor deposition (PECVD), or an atomic layer deposition (ALD).

Referring back to FIGS. 3 and 7A, a word line WL and a gate dielectric pattern Gox are formed. The word line WL is formed to include a first word line WL1 on the first vertical part V1 and a second word line WL2 on the second vertical part V2. The formation of the word line WL includes, for example, removing the conductive layer CL from the first dielectric pattern 130 and the horizontal part H to form a plurality of word lines WL that are separated from each other.

For example, when the word line WL is formed, the gate dielectric layer GIL on the first dielectric pattern 130 and the horizontal part H is removed to form a plurality of gate dielectric patterns Gox that are separated from each other. Alternatively, when the word line WL is formed, the gate dielectric layer GIL on the first dielectric pattern 130 is removed to form a plurality of gate dielectric patterns Gox, and the gate dielectric layer GIL on the horizontal part H is not removed but remains to constitute a portion of the gate dielectric pattern Gox. For example, the gate dielectric pattern Gox has a U shape that is connected to each other on the horizontal part H.

When the word line WL and the gate dielectric pattern Gox are formed, a portion of the horizontal part H of the semiconductor pattern SP is further removed. For example, the horizontal part H is divided into first and second sub-horizontal parts that are respectively connected to the first and second vertical parts V1 and V2, and the first and second sub-horizontal parts are spaced apart from each other. The first vertical part V1 and the first sub-horizontal part are connected to each other and have an L shape, and the second vertical part V2 and the second sub-horizontal part are connected to each other and have an L shape.

A portion of the protection layer 112 is removed in the removal process. After the removal process, an additional protection layer is formed on a residue of the protection layer 112, and the residue of the protection layer 112 and the additional protection layer constitute a protection pattern 110.

A first dielectric pattern 130 is formed between the first word line WL1 and the second word line WL2. The first dielectric pattern 130 fills the trench region TR. The formation of the first dielectric pattern 130 includes forming a first dielectric layer that fills the trench region TR and covers the semiconductor pattern SP, the gate dielectric pattern Gox, and the word line WL, and removing an upper portion of the first dielectric layer to form a plurality of first dielectric patterns 130 that are separated from each other.

The first dielectric pattern 130 is formed to have a top surface located at a same height (level) as a top surface of the word line WL, and lower than a top surface of the gate dielectric pattern Gox and the top surfaces of the semiconductor dielectric patterns 120. Therefore, a first recess region is formed that exposes the top surface of the first dielectric pattern 130 and the top surface of the word line WL. The first recess region extends along the second direction D2.

A capping pattern 220 is formed that fills the first recess region. The formation of the capping pattern 220 includes forming a capping layer that fills the first recess region and covers the top surfaces of the semiconductor dielectric patterns 120, and removing an upper portion of the capping layer to form a plurality of capping patterns 220 that are separated from each other. When the capping pattern 220 is formed, the top surfaces of the semiconductor dielectric patterns 120 are outwardly exposed, and top surfaces of the first and second vertical parts V1 and V2 are also outwardly exposed.

Landing pads LP are formed on the first and second vertical parts V1 and V2 of the semiconductor pattern SP. The formation of the landing pads LP includes removing upper portions of the first and second vertical parts V1 and V2 to form a second recess region, forming a landing pad layer that fills the second recess region and covers the capping pattern 220, and removing a portion of the landing pad layer to form a plurality of landing pads LP that are separated from each other.

A third interlayer dielectric layer 240 is formed that fills a space between the landing pads LP on the semiconductor dielectric patterns 120 and the first dielectric patterns 130. Data storage patterns DSP are correspondingly formed on the landing pads LP. The data storage patterns DSP are electrically connected through the landing pads LP to the first and second vertical parts V1 and V2 of the semiconductor pattern SP. Thus, a semiconductor memory device according to some embodiments of the present inventive concepts can be fabricated.

In a semiconductor memory device according to some embodiments of the present inventive concepts, a semiconductor dielectric pattern disposed between semiconductor patterns includes an air gap and sidewall dielectric patterns formed of a metal oxide. Therefore, the semiconductor patterns have increased mobility, and a parasitic capacitance can be prevented.

In addition, as the semiconductor dielectric pattern includes an upper capping pattern, landing pads have increased resistance and the introduction of hydrogen can be blocked. In conclusion, a semiconductor memory device according to embodiments has increased reliability and electrical properties.

Although embodiments of the present inventive concepts have been described in connection with the accompanying drawings, it will be understood to those skilled in the art that various changes and modifications may be made without departing from the technical spirit and essential feature of the present inventive concepts. It will be apparent to those skilled in the art that various substitutions, modifications, and changes may be thereto without departing from the scope and spirit of the present inventive concepts.

What is claimed is:

1. A semiconductor memory device, comprising:
a bit line that extends in a first direction;
a plurality of semiconductor patterns disposed on the bit line and that are spaced apart from each other in the first direction, wherein each of the semiconductor patterns includes a first vertical part, a second vertical part opposite to the first vertical part in the first direction, and a horizontal part that connects the first and second vertical parts to each other;
a first word line and a second word line that are disposed on the horizontal part and respectively adjacent to the first vertical part and the second vertical part; and
a semiconductor dielectric pattern disposed on the bit line and interposed between the semiconductor patterns,
wherein the semiconductor dielectric pattern includes:
a lower capping pattern;
a plurality of sidewall dielectric patterns disposed on the lower capping pattern and that are spaced apart from each other in the first direction;
an air gap interposed between the sidewall dielectric patterns; and
an upper capping pattern disposed on the sidewall dielectric patterns,
wherein a height of top surfaces of the sidewall dielectric patterns is a same as a height of top surfaces of the first and second vertical parts.

2. The device of claim 1, wherein the sidewall dielectric patterns are correspondingly interposed between the air gap and the semiconductor patterns.

3. The device of claim 1, wherein the sidewall dielectric patterns include metal oxide.

4. The device of claim 1, wherein the sidewall dielectric patterns include at least one of hafnium (Hf) oxide, silicon (Si) oxide, aluminum (Al) oxide, zirconium (Zr) oxide, titanium (Ti) oxide, tantalum (Ta) oxide, niobium (Nb) oxide, lanthanum (La) oxide, barium (Ba) oxide, strontium (Sr) oxide, yttrium (Y) oxide, or ruthenium (Lu) oxide.

5. The device of claim 1, wherein the sidewall dielectric patterns are in direct contact with corresponding semiconductor patterns.

6. The device of claim 1, wherein the air gap is surrounded by the lower capping pattern, the upper capping pattern, and the sidewall dielectric patterns.

7. The device of claim 1, wherein the upper capping pattern is in direct contact with the top surfaces of the sidewall dielectric patterns.

8. The device of claim 1, wherein the lower capping pattern is in direct contact with a top surface of the bit line.

9. The device of claim 1, further comprising a gate dielectric pattern interposed between the first vertical part and the first word line and between the second vertical part and the second word line.

10. The device of claim 9, wherein the gate dielectric pattern is spaced apart from the semiconductor dielectric pattern.

11. A semiconductor memory device, comprising:
a bit line that extends in a first direction;
a plurality of semiconductor patterns disposed on the bit line and that are spaced apart from each other in the first direction, wherein each of the semiconductor patterns includes a first vertical part, a second vertical part opposite to the first vertical part in the first direction, and a horizontal part that connects the first and second vertical parts to each other;
a first word line and a second word line that are disposed on the horizontal part and respectively adjacent to the first vertical part and the second vertical part;
a plurality of landing pads disposed on the first and second vertical parts; and
a semiconductor dielectric pattern disposed on the bit line and interposed between the semiconductor patterns,
wherein the semiconductor dielectric pattern includes an air gap and a barrier pattern that surrounds the air gap, and
wherein a sidewall of the barrier pattern includes a metal oxide.

12. The device of claim 11, wherein the barrier pattern includes:
an upper capping pattern adjacent to the landing pads;
a lower capping pattern adjacent to the bit line; and
a sidewall dielectric pattern that connects the upper capping pattern to the lower capping pattern,
wherein the sidewall dielectric pattern includes a metal oxide.

13. The device of claim 11, wherein the metal oxide includes at least one of hafnium (Hf) oxide, silicon (Si) oxide, aluminum (Al) oxide, zirconium (Zr) oxide, titanium (Ti) oxide, tantalum (Ta) oxide, niobium (Nb) oxide, lanthanum (La) oxide, barium (Ba) oxide, strontium (Sr) oxide, yttrium (Y) oxide, or ruthenium (Lu) oxide.

14. The device of claim 11, wherein the barrier pattern is in direct contact with the semiconductor patterns.

15. The device of claim 11, wherein a top surface of the air gap is at a same height as top surfaces of the first and second vertical parts of the semiconductor pattern.

16. The device of claim 12, wherein the upper capping pattern is in direct contact with the landing pad.

17. The device of claim 11, further comprising a gate dielectric pattern interposed between the first vertical part and the first word line and between the second vertical part and the second word line.

18. The device of claim 17, wherein the gate dielectric pattern is spaced apart from the semiconductor dielectric pattern.

19. A semiconductor memory device, comprising:
a plurality of bit lines that extend in a first direction, wherein the bit lines are spaced apart from each other in a second direction that is orthogonal to the first direction;
a semiconductor pattern disposed on each of the bit lines and that is spaced apart from each other in the first direction, wherein each of the semiconductor patterns includes a first vertical part, a second vertical part opposite in the first direction to the first vertical part, and a horizontal part that connects the first and second vertical parts to each other;
a first word line and a second word line that are disposed on the horizontal part and respectively adjacent to the first vertical part and the second vertical part;
a gate dielectric pattern interposed between the first vertical part and the first word line and between the second vertical part and the second word line;
a plurality of semiconductor dielectric patterns respectively disposed on each of the bit lines and interposed between the semiconductor patterns, wherein the semiconductor dielectric patterns are in direct contact with the bit lines;
a plurality of landing pads disposed on the first and second vertical parts; and
a plurality of data storage patterns respectively disposed on corresponding landing pads,
wherein the semiconductor dielectric patterns include:
a lower capping pattern disposed on each of the bit lines;
a plurality of sidewall dielectric patterns disposed on the lower capping pattern;
an air gap formed between the sidewall dielectric patterns; and
an upper capping pattern disposed on the sidewall dielectric patterns,
wherein top surfaces of the sidewall dielectric patterns are at a same height as top surfaces of the first and second vertical parts of the semiconductor pattern, and
wherein the sidewall dielectric patterns include a metal oxide.

20. The device of claim 19, wherein the sidewall dielectric patterns are in direct contact with the semiconductor patterns.
